(19) United States
(12) Patent Application Publication
(10) Pub. No.: US 2021/0178381 A1
(43) Pub. Date: Jun. 17, 2021

(54) METHOD FOR PREPARING CATALYTIC NANOPARTICLES, CATALYST SURFACES, AND/OR CATALYSTS

(71) Applicants: AGC GLASS EUROPE, Louvain-la-Neuve (BE); AGC INC., Chiyoda Ku (JP); AGC FLAT GLASS NORTH AMERICA, INC., Alpharetta, GA (US); AGC VIDROS DO BRASIL LTDA, Sao Paulo (BR)

(72) Inventors: Denis BUSARDO, Gonneville Sur Mer (FR); Lionel VENTELON, Nivelles (BE)

(73) Assignees: AGC GLASS EUROPE, Louvain-la-Neuve (BE); AGC INC., Chiyoda Ku (JP); AGC FLAT GLASS NORTH AMERICA, INC., Alpharetta, GA (US); AGC VIDROS DO BRASIL LTDA, Sao Paulo (BR)

(21) Appl. No.: 17/251,012

(22) PCT Filed: Jun. 11, 2019
(86) PCT No.: PCT/EP2019/065238

§ 371 Date: Dec. 10, 2020

(30) Foreign Application Priority Data
Jun. 12, 2018 (EP) 18177331.8

(51) Int. Cl. B01J 37/34; B01J 23/42; B01J 23/44; B01J 23/46; B01J 29/00; B01J 37/00

(52) U.S. Cl. CPC B01J 37/347; B01J 23/42; B01J 23/44; B82Y 30/00; B01J 29/005; B01J 37/0072; B01J 23/464

(57) ABSTRACT

A method for preparing catalyst particles that includes providing an average atomic number Zavr for a catalyst starting material, providing an ion beam having an ion beam current and selecting an ion beam dose X expressed in ions/g, based on the weight of the catalyst starting material, where X follows the following equations: (7/Zavr)×10¹⁸ ions/g<X<(7/Zavr)×6×10¹⁹ ions/g, implanting the catalyst starting material with an ion beam dose X primarily comprising the selected ions, where the ratio of the current of the ion beam current to the cross-section area of the ion beam, measured at the point of contact with the catalyst starting material is at least 1.2 μA/mm², thereby obtaining a catalyst. The resulting catalyst particles are useful in NOx, CO, and/or HC emission reduction devices, fuel cells, or catalysts in chemical reactions.

### FIELD OF THE INVENTION

The invention relates to the preparation of catalytic particles, catalyst surfaces, or catalysts, more in particular to the preparation of catalytic particles, catalyst surfaces, or catalysts suitable to be used in pollution emission treatments of exhaust gasses, for example from vehicle combustion engines.

### BACKGROUND OF THE INVENTION

Currently catalyst particles are known and used for the reduction of pollution emission. Typically, catalyst particles are arranged in a catalytic converter, which is fluidly connection to the exhaust of a vehicle combustion engine.

As the catalytic material is often rare, expensive and/or environmentally unfriendly at the end of its life cycle, there is a demand to elevate or to maximise the catalytic activity of a certain amount of catalytic material.

There is a further demand for production methods that have a high yield and preferably do not generate a lot of waste material, e.g. catalytic material that is too small or too large to be of use. There is a demand for more homogeneous catalyst particles in terms of size and/or activity. There is a demand to provide catalyst particles of which the catalytic activity stays stable over a period of time. There is a demand for catalyst particles which are resistant to aging. There is a demand for catalyst particles to be homogeneously dispersed over a support, and preferably so that the dispersion remains stable over time.

It is accordingly one of the objects of the present invention to overcome or ameliorate one or more of the aforementioned disadvantages present in the market, or to meet any of the demands that are present in the market. Preferably, the invention also provides in a reliable production process.

### SUMMARY OF THE INVENTION

The present inventors have now surprisingly found that one or more of these objects can be obtained by specific ion beam implantation of catalytic material. While the exact reasons behind the observed improvements are still not completely understood, it appears that the inventive method can cause defects in and/or on the catalyst, the catalyst particles and/or support nanoparticles that lead to the observed improvements. The inventive method can cause amorphisation of the catalyst, the catalytic nanoparticles, or support. The obtained catalyst surfaces, catalysts, or catalyst particles are more reactive than the catalyst starting material. The obtained catalyst surfaces, catalysts, or catalyst particles are more homogeneous in terms of catalytic activity than other catalyst particles known in the art or the catalytic starting material.

The catalyst particles are aggregates of support nanoparticles with surface attached metal nanoparticles, that is, aggregates of support nanoparticles onto the surface of which metal nanoparticles are physically or chemically formed and attached. The catalyst particles may loosely agglomerate so as to form a catalyst powder particles and may be bound on a carrier to form a catalyst, when used for example in a catalytic converter. Any of the support nanoparticles, catalyst particles, catalyst powder or catalyst may form the catalytic starting material in the present invention. Any of the support nanoparticles, catalyst particles, catalyst powder or catalyst, after the method of the present invention has been performed is termed the obtained catalyst. When the catalyst starting material are catalyst particles of metal nanoparticles bound on aggregated support nanoparticles, after the method has been performed, the metal nanoparticles are more homogeneously dispersed over the support than before the method is performed, even after aging.

It was unexpectedly found that the inventive method provides an obtained catalyst that is resistant to decay. Preferably, the catalytic activity of the obtained catalyst does not decay more than 10% every year, more preferably not more than 7% every year, even more preferably not more than 5% every year, still more preferably not more than 3% every year, and most preferably not more than 1% every year.

More homogeneously sized catalyst particles lead to a better control over catalytic properties of the obtained catalyst and preferably more homogeneous catalytic converters. It allows for less excess catalytic materials to be used. The method of the present invention, due to the choses parameters of ion implantation, leads to less fragmentation and explosion of the catalytic material, so less dust is generated and less material with a too small diameter to be of use is generated.

It was unexpectedly found that the inventive method provides the obtained catalyst, in particular catalyst particles in a high yield. Preferably, the method provides the obtained catalyst, in particular catalyst particles, with a yield of at least 0.60, more preferably at least 0.70, even more preferably at least 0.80 and most preferably at least 0.90, wherein the yield is calculated as the ratio of the weight of the obtained catalyst divided by the weight of the catalyst starting material.

It was unexpectedly found that less catalytic material is removed during the method in gas streams or by vacuum pumps. It was observed that less static electricity is built up on and around the catalytic material. This was found to be further improved by addition of UV sources, soft X-ray sources or electron beam sources.

A higher catalytic activity was observed after the method has been performed, compared to the catalytic starting material. The catalyst, in particular the catalyst particles obtained by the method are active at a much lower temperature than the untreated catalytic starting material, preferably the obtained catalyst particles have a peak activity laying in the temperature range of at least 40° C. to at most 80° C., preferably determined by temperature programmed reduction (TPR) experiments.

The invention provides a method for preparing catalyst particles, a catalyst surface, or a catalyst, comprising the steps of:
a. providing a catalytic starting material; and,
b. implanting the catalytic starting material with an ion beam dose;
   thereby obtaining catalyst particles, a catalyst surface, or a catalyst.

It has been found that by changing the energy of ions in the ion beam, the penetration depth is influenced. This further results in a higher efficient treatment of the catalytic starting material. It also has been found that changing the atomic number of the ions in the ion beam is connected to the way fragmentation occurs of the catalytic starting material or is avoided. It also appears that that the effect of a certain atomic number ion may not be obtained by using a different atomic number ion but with an amended energy or dose. The penetration depth may be such that the implanted ion travels through one or more catalyst particles before all its energy is spent. It appears that even if the ion itself does not remain in the penetrated catalyst particle, the defects created on its trajectory improve the catalytic properties. The energy of the ions is chosen so as to have limit or negligible amounts of sputtering.

FIG. 3 illustrates how support nanoparticles (1) and metal nanoparticles (2) aggregate to form catalyst particles 3. These catalyst particles (3) may agglomerate to form catalyst powder (4).

In some embodiments, the catalyst starting material is a support nanoparticle or an aggregate of support nanoparticles. After ion implantation metal nanoparticles are formed and bonded on the surface of the support nanoparticle aggregates.

In some embodiments, the catalyst starting material is a catalyst particle, that is an aggregate of metal nanoparticles on support nanoparticles.

In some embodiments, the metal nanoparticles are preferably physically or chemically attached to an aggregate of support nanoparticles. The metal nano particles may be bound to the support by strong metal-support interactions such as metal-oxide bonds, e.g. Pt—O, wherein the oxygen atom forms part of the support, or metal-oxide-cerium bonds or metal-oxide-aluminium bonds, e.g. Pt—O—Ce or Pt—O—Al.

In some embodiments, the support material is an aluminium oxide preferably Al₂O₃, or a cerium oxide, preferably CeO₂ or a mixed oxide of Cerium and Zirconium, such as for instance Ce_{0.7}Zr_{0.3}O₂ or Ce_{0.5}Zr_{0.5}O₂.

In some embodiments, the ratio of the weight of the metal nanoparticles over the weight of the support nanoparticles is at least 0.1 wt % to at most 5.0 wt %, preferably 0.3 wt % to at most 3.0 wt %, more preferably at least 0.5 wt % to at most 2.0 wt %, and most preferably at least 0.7 wt % to at most 1.5 wt %.

In some embodiments, at least part of the ions, preferably all ions, are derived from atoms with atomic number Z of at most 7, preferably at most 6, more preferably at most 2.

In some embodiments, at least part of the ions, preferably all ions, are derived from helium atoms, argon atoms, oxygen atoms and/or nitrogen atoms.

In some embodiments, Zₐᵥᵣ is at most 20, preferably at most 14, more preferably at most 10, even more preferably at most 7 and most preferably at most 4.

In some embodiments, at least 50% of the ions, preferably at least 75% of the ions, more preferably at least 90% of the ions, even more preferably at least 95% of the ions and most preferably 100% of the ions are derived from helium atoms, argon atoms, oxygen atoms and/or nitrogen atoms.

In some embodiments, the method comprises n different implanting steps with n multiple doses Xᵢ, preferably wherein each dose Xᵢ is X/n, X being the total ion beam dose.

In some embodiments, the incident angle between the ion beam and the surface normal is 0° to at most 45°, preferably 0° to at most 30°, more preferably 0° to at most 20°, even more preferably 0° to at most 10°, yet more preferably 0° to at most 5° and most preferably 0°. The smaller the incident angle the deeper the material may be treated with the ion beam. The surface of reference is the surface of the carrier on which the catalytic starting material is evenly distributed for undergoing the ion implantation.

In some embodiments, the metal nanoparticles comprise a transition metal, preferably a noble metal.

In some embodiments, the metal nanoparticles comprise platinum (Pt) or palladium (Pd) or Rhodium (Rh).

In some embodiments, the metal nanoparticles comprise ruthenium, gold or copper.

The invention further provides support nanoparticles or a catalyst particles produced by a method according to the invention.

The invention further also provides in a use of the catalyst particles prepared according to the method according to the invention in NOx, CO, and/or HC emission reduction devices, fuel cells, or catalyst in chemical, in particular petrochemical, reactions.

Preferred embodiments of the invention are disclosed in the detailed description and appended claims. In the following passages different aspects of the invention are defined in more detail. Each aspect so defined may be combined with any other aspect or aspects unless clearly indicated to the contrary. In particular, any feature indicated as being preferred or advantageous may be combined with any other feature or features indicated as being preferred or advantageous. (Preferred) embodiments of one aspect of the invention are also (preferred) embodiments of all other aspects of the invention.

### BRIEF DESCRIPTION OF THE FIGURES

FIG. 1 shows a HRTEM-image of catalytic particles according to an embodiment of the invention, defects such as terraces and vacancies may be noticed on the surface of the catalytic nanoparticles.

FIG. 2 shows the H₂ consumption in TPR experiments of untreated and ion bombarded catalytic nanoparticles.

FIG. 3 is a schematic representation of metal and support nanoparticles, catalytic particles and catalyst powder of the present invention.

### DETAILED DESCRIPTION OF THE INVENTION

When describing the invention, the terms used are to be construed in accordance with the following definitions, unless a context dictates otherwise.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to a person skilled in the art from this disclosure, in one or more embodiments. Furthermore, while some embodiments described herein include some but not other features included in other embodiments, combinations of features of different embodiments are meant to be within the scope of the invention, and form different embodiments, as would be understood by those in the art.

As used in the specification and the appended claims, the singular forms “a”, “an,” and “the” include plural referents unless the context clearly dictates otherwise. By way of example, “a particle” means one particle or more than one particle.

Unless defined otherwise, all technical and scientific terms used herein have the same meaning as is commonly understood by one of skill in the art. All publications referenced herein are incorporated by reference thereto.

Throughout this application, the term ‘about’ is used to indicate that a value includes the standard deviation of error for the device or method being employed to determine the value.

The recitation of numerical ranges by endpoints includes all integer numbers and, where appropriate, fractions subsumed within that range (e.g. 1 to 5 can include 1, 2, 3, 4 when referring to, for example, a number of elements, and can also include 1.5, 2, 2.75 and 3.80, when referring to, for example, measurements). The recitation of end points also includes the end point values themselves (e.g. from 1.0 to 5.0 includes both 1.0 and 5.0). Any numerical range recited herein is intended to include all sub-ranges subsumed therein.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to a person skilled in the art from this disclosure, in one or more embodiments. Furthermore, while some embodiments described herein include some but not other features included in other embodiments, combinations of features of different embodiments are meant to be within the scope of the invention, and form different embodiments, as would be understood by those in the art. For example, in the following claims and statements, any of the embodiments can be used in any combination.

The terms “ion implantation” and “ion bombardment” are used herein as synonyms. The terms “catalyst particle” and “catalytic particle” are used herein as synonyms.

Preferred statements (features) and embodiments of the catalyst particles, catalyst surfaces, catalyst, processes, articles, and uses of this invention are set herein below. Each statement and embodiment of the invention so defined may be combined with any other statement and/or embodiment, unless clearly indicated to the contrary. In particular, any feature indicated as being preferred or advantageous may be combined with any other features or statements indicated as being preferred or advantageous.

Hereto, the present invention is in particular captured by any one or any combination of one or more of the below numbered statement and embodiments, with any other statement and/or embodiment.
1. Method for preparing catalyst particles, a catalyst surface, or a catalyst, comprising the steps of:
   providing a catalytic starting material, comprising support nanoparticles and optionally metal nanoparticles; and,
   providing an ion beam,
   implanting the catalyst starting material with an ion beam dose, wherein the ion beam comprises selected monocharged ions or a mixture of selected monocharged and multicharged ions; the monocharged and multicharged ions being positively charged ions,
      thereby obtaining catalyst particles, a catalyst surface, or a catalyst.
2. Method according to statement 1, preferably a method for preparing catalyst particles, a catalyst surface, or a catalyst comprising the steps of:
   providing a catalyst starting material, comprising catalyst particles made of aggregates of support nanoparticles with surface attached metal nanoparticles;
   providing an average atomic number Zₐᵥᵣ;
   selecting an ion beam with a dose X expressed in ions/g, based on the weight of the catalyst starting material, and wherein X follows the following in equations:

(7/Zₐᵥᵣ)×10¹⁸ ions/g<X<(7/Zₐᵥᵣ)×6×10¹⁹ ions/g,
and preferably with an energy of the monocharged ions in the ion beam from at least 10 keV to at most 100 keV; and,
implanting the catalyst starting material with an ion beam dose X primarily comprising the selected ions;
   thereby obtaining catalyst particles, a catalyst surface, or a catalyst.
3. Method according to any one of statements 1 to 2, preferably a method for preparing a catalyst particles, a catalyst surface, or a catalyst, comprising the steps of:
   providing a catalyst starting material, comprising metal nanoparticles size with an average diameter D_{avr,metal}
   providing a minimum number of defects N per volume unit of catalyst;
   selecting ions with an average atomic number Zₐᵥᵣ, wherein Zₐᵥᵣ follows the following in equations:

INT(0.5×D_{avr,met}×1/nm)<Zₐᵥᵣ<INT(2.0×D_{avr,met}×1/nm); and,
implanting the catalyst starting material with an ion beam dose primarily comprising the selected ions preferably with an energy of the monocharged ions in the ion beam from at least 10 keV to at most 100 keV;
   thereby obtaining catalyst particles, a catalyst surface, or a catalyst.
4. Method according to any one of statements 1 to 3, preferably a method for preparing a catalyst particles, a catalyst surface, or a catalyst, comprising the steps of:
   providing ions with an atomic number Z;
   providing a minimum number of defects N per volume unit of catalyst particle;
   selecting a catalyst starting material; and,
   implanting the catalyst starting material with an ion beam dose primarily comprising the selected ions preferably with an energy of the monocharged ions in the ion beam from at least 10 keV to at most 100 keV;
      thereby obtaining catalyst particles, a catalyst surface, or a catalyst.
5. Method according to any one of statements 1 to 4, preferably a method for preparing a catalyst particles, a catalyst surface, or a catalyst, comprising the steps of:
   providing a catalyst starting material; and,
   implanting the catalyst starting material with an ion beam, while simultaneously treating the catalyst starting material with a source providing one or more of the following: UV light, X-rays, and/or an electron beam;
      thereby obtaining catalyst particles, a catalyst surface, or a catalyst.
6. Method according to any one of statement 1 to 5, wherein the energy (E) of the monocharged ions in the ion beam is at least 10 keV and at most 100 keV.
7. Method according to any one of statements 1 to 6, wherein the energy E of the monocharged ions in the ion beam is at least 10 keV, preferably at least 20 keV, more preferably at least 30 keV, even more preferably at least 40 keV and most preferably at least 50 keV.
8. Method according to any one of statements 1 to 7, wherein the energy E of the monocharged ions in the ion beam is at most 100 keV, preferably at most 90 keV, more preferably at most 80 keV, even more preferably at most 70 keV and most preferably at most 60 keV.
9. Method according to any one of statements 1 to 8, wherein the energy E of the monocharged ions in the ion beam is at least 10 keV to at most 100 keV, preferably at least 20 keV to at most 90 keV, more preferably at least 30 keV to at most 80 keV, even more preferably at least 40 keV to at most 70 keV and most preferably at least 50 keV to at most 60 keV.
10. Method according to any one of statements 1 to 9, wherein the ion beam is generated by a plasma filament ion beam source or an electron cyclotron resonance (ECR) plasma source, such as an ECR Plasma Immersion ion implantation (PIII) or preferably an ECR plasma confined with permanent magnets.
11. Method according to any one of statements 1 to 10, wherein the ions in the ion beam are extracted by a extraction voltage of at least 5 kV, preferably at least 10 kV, more preferably at least 15 kV, even more preferably at least 20 kV, yet even more preferably at least 25 kV and most preferably at least 30 kV.
12. Method according to any one of statements 1 to 11, wherein the energy E of the monocharged and multicharged ions in the ion beam is at most 150 keV, preferably at most 125 keV, more preferably at most 100 keV.
13. Method according to any one of statements 1 to 12, wherein the monocharged and multicharged ions in the ion beam are extracted by an extraction voltage of at least 5 kV to at most 100 kV, preferably at least 10 kV to at most 100kV, more preferably at least 15 kV to at most 125 kV, even more preferably at least 20 kV to at most 100 kV, yet even more preferably at least 25 kV to at most 75 kV and most preferably at least 30 kV to at most 50 kV, such as 35 kV.
14. Method according any one of statements 1 to 13, wherein the dose X, expressed in ions/g, based on the weight of the catalyst starting material, of the ion beam, follows the following in equations:

(7/Zₐᵥᵣ)×10¹⁸ ions/g<X<(7/Zₐᵥᵣ)×3×10¹⁹ ions/g;
for example wherein the dose follows one or more of the following in equations:

2×(7/Zₐᵥᵣ)×10¹⁸ ions/g<X<(7/Zₐᵥᵣ)×2×10¹⁹ ions/g; or,

5×(7/Zₐᵥᵣ)×10¹⁸ ions/g<X<(7/Zₐᵥᵣ)×1×10¹⁹ ions/g.
15. Method according any one of statements 1 to 14, wherein Zₐᵥᵣ follows the following in equations:

INT(0.5×D_{avr, metal}×1/nm)<Zₐᵥᵣ<INT(1.0×D_{avr,metal}×1/nm);

for example wherein Zₐᵥᵣ follows one or more of the following in equations:

INT(0.6×D_{avr,metal}×1/nm)<Zₐᵥᵣ<INT(0.9×D_{avr,metal}×1/nm); or

INT(0.7×D_{avr,metal}×1/nm)<Zₐᵥᵣ<INT(0.8×D_{avr,metal}×1/nm).
16. Method according any one of statements 1 to 15, wherein the ion beam dose is at least 10¹³ ions/cm², preferably at least 10¹⁴ ions/cm², even more preferably at least 10¹⁵ ions/cm².
17. Method according any one of statements 1 to 16, wherein the ion beam dose is at most 10¹⁸ ions/cm², preferably at most 10¹⁷ ions/cm², even more preferably at most 10¹⁶ ions/cm².
18. Method according any one of statements 1 to 17, wherein the ion beam dose is at least 10¹³ ions/cm² to at most 10¹⁸ ions/cm², preferably at least 10¹⁴ ions/cm² to at most 10¹⁷ ions/cm², even more preferably at least 10¹⁵ ions/cm² to at most 10¹⁶ ions/cm², such as 5×10¹⁵ ions/cm².
19. Method according any one of statements 1 to 18, wherein the current of the ion beam or the intensity of the ion beam is at least 0.1 mA, preferably at least 0.2 mA, more preferably at least 0.5 mA, even more preferably at least 0.7 mA, and most preferably at least 0.9 mA.
20. Method according any one of statements 1 to 19, wherein the current of the ion beam or the intensity of the ion beam is at most 10.0 mA, preferably at most 7.0 mA, more preferably at most 5.0 mA, even more preferably at most 3.0 mA, and most preferably at most 1.5 mA.
21. Method according any one of statements 1 to 20, wherein the current of the ion beam or the intensity of the ion beam is at least 0.1 mA to at most 10.0 mA, preferably at least 0.2 mA to at most 7.0 mA, more preferably at least 0.5 mA to at most 5.0 mA, even more preferably at least 0.7 mA to at most 3.0 mA, and most preferably at least 0.9 to at most 1.5 mA, such as 1.0 mA.
22. Method according any one of statements 1 to 21, wherein the ion beam moves over the catalytic starting material at a speed of at least 10 mm/s to at most 500 mm/s, preferably at least 20 mm/s to at most 300 mm/s. more preferably at least 40 mm/s to at most 150 mm/s and most preferably at least 60 mm/s to at most 120 mm/s, such as 80 mm/s.
23. Method according any one of statements 1 to 22, wherein the total ion beam dose is split into m partial ion beam doses, and wherein the catalytic starting material is mixed or stirred each time between the m different ion beam doses, preferably m is at least 4 to at most 64, more preferably at least 8 to at most 32, even more preferably at least 12 to at most 24 and most preferably at least 16 to at most 18.
24. Method according any one of statements 1 to 23, wherein the advancement step of the ion beam is at least 1% to at most 50%, preferably at least 2% to at most 40%, more preferably at least 5% to at most 30%, even more preferably at least 7% to at most 20% and most preferably at least 10% to at most 15%.
25. Method according any one of statements 1 to 24, wherein the diameter of the ion beam is at least 5 mm to at most 100 mm, preferably at least 10 mm to at most 75 mm, more preferably at least 15 mm to at most 60 mm, even more preferably at least 25 mm to at most 50 mm, and most preferably at least 35 mm to at most 40 mm, measured at the point of contact with the catalyst starting material.
26. Method according to any one of statements 1 to 25, wherein the catalyst starting material is provided on a carrier.
27. Method according to any one of statements 1 to 26, for preparing catalyst particles on a carrier, a catalyst surface, on a carrier, or a catalyst on a carrier, preferably physically or chemically attached to a support. The carrier may be of metal, of ceramic, such as cordierite for example, or also of glass fibre. The carrier may be formed as a rigid sheet or tube, as a honeycomb structure or as a flexible mat.
28. Method according to any one of statements 1 to 27, wherein the catalyst starting material comprises support nanoparticles and wherein the support nanoparticles comprise or consist of an aluminium oxide, a cerium oxide, a zirconium oxide, a mixed cerium-zirconium oxide, a titanium oxide or a zeolite.
29. Method according to any one of statements 1 to 28, wherein the support is Al₂O₃, CeO₂ or Ce_{0.7}Zr_{0.3}O₂ Ce_{0.5}Zr_{0.5}O₂.
30. Method according to any one of statements 1 to 29, wherein the catalyst starting material comprises support nanoparticles and wherein the support nanoparticles comprise or consist of is selected from the list comprising: zeolites; La- , Pr- , or Nd-doped Al₂O₃; CeO₂; Zr-doped CeO₂; specific stabilised Zr-Oxide; Al₂O₃; SiO₂-doped Al₂O₃; ZrO₂—SiO₂, Ba-doped Al₂O₃, TiO₂; W-doped TiO₂; Mo-doped TiO₂; W- and Mo-codoped TiO₂ and Fe—Cu—doped Zeolite.
31. Method according to any one of statements 1 to 30, wherein the catalyst starting material comprises metal nanoparticles and support nanoparticles and wherein the ratio of the weight of the metal nanoparticles over the weight of the support nanoparticles is at least 0.1 wt % to at most 5.0 wt %, preferably 0.3 wt % to at most 3.0 wt %, more preferably at least 0.5 wt % to at most 2.0 wt %, and most preferably at least 0.7 wt % to at most 1.5 wt %.
32. Method according to any one of statements 1 to 31, wherein at least part of the ions, preferably all ions, are derived from atoms with an atomic number Z of at most 18, preferably at most 10, more preferably at most 8, even more preferably at most 7, most preferably at most 2.
33. Method according to any one of statements 1 to 32, wherein at least part of the ions, preferably all ions, are derived from helium atoms, argon atoms, oxygen atoms and/or nitrogen atoms.
34.Method according to any one of statements 1 to 33, wherein Zₐᵥᵣ is at most 20, preferably at most 14, more preferably at most 10, even more preferably at most 7 and most preferably at most 4.
35. Method according to any one of statements 1 to 34, wherein at least 50% of the ions, preferably at least 75% of the ions, more preferably at least 90% of the ions, even more preferably at least 95% of the ions and most preferably 100% of the ions are derived from helium atoms, argon atoms, oxygen atoms and/or nitrogen atoms.
36. Method according to any one of statements 1 to 35, wherein the metal nanoparticle size D_{avr,metal} is at most 100.0 nm, preferably at most 75.0 nm, more preferably at most 50.0 nm, even more preferably at most 25.0 nm, yet even more preferably at most 15.0 nm and most preferably at most 10.0 nm.
37. Method according to any one of statements 1 to 36, wherein the metal nanoparticle size D_{avr,metal} is at least 0.1 nm, preferably at least 0.5 nm, more preferably at least 1.0 nm, even more preferably at least 5.0 nm, and most preferably at least 7.0 nm.
38. Method according to any one of statements 1 to 37, wherein the metal nanoparticle size D_{avr,metal} is at least 0.1 nm to at most 100.0 nm, preferably at least 0.5 nm to at most 75.0 nm, more preferably at least 1.0 nm to at most 50.0 nm, even more preferably at least 5.0 nm to at most 25.0 nm, yet even more preferably at least 7.0 nm to at most 15 nm and most preferably at least 10.0 nm to at most 12.0 nm.
39. Method according to any one of statements 1 to 38, wherein the catalyst starting material comprises metal nanoparticles and support nanoparticles.
40. Method according to any one of statements 1 to 39, wherein the support nanoparticles are larger in diameter than the metal nanoparticles, preferably at least 20% larger, more preferably at least 50% larger, even more preferably at least 100% larger, yet more preferably at least 200% larger and most preferably at least 300% larger.
41. Method according to any one of statements 1 to 40, wherein the catalytic particle size D_{avr,cat} is at most 200.0 nm, alternately at most 150.0 nm, alternately at most 100.0 nm.
42. Method according to any one of statements 1 to 41, wherein the catalyst particle size D_{avr,cat} is at least 10 nm, alternately at least 20 nm, alternately at least 30 nm, alternately at least 50 nm.
43. Method according to any one of statements 1 to 42, wherein the catalyst particle size D_{avr,cat} is at least 10 nm to at most 200.0 nm, alternately at least 20 nm to at most 150.0 nm, alternately at least 30 nm to at most 100.0 nm.
44. Method according to any one of statements 1 to 43, wherein the catalyst starting material is a catalytic powder.
45. Method according to any one of statements 1 to 44, wherein the catalyst starting material comprises a crystalline fraction.
46. Method according to any one of statements 1 to 45, comprising n different implanting steps with n multiple doses Xi, preferably wherein each dose Xi is X/n, X being the total ion beam dose.
47. Method according to any one of statements 1 to 46, wherein the incident angle between the ion beam and the surface normal is 0° to at most 45°, preferably 0° to at most 30°, more preferably 0° to at most 20°, even more preferably 0° to at most 10°, yet more preferably 0° to at most 5° and most preferably 0°.
48. Method according to any one of statements 1 to 47, wherein the catalyst starting material comprises a transition metal, preferably a noble metal.
49. Method according to any one of statements 1 to 48, wherein the catalyst starting material comprises metal nanoparticles comprising or consisting of a material selected from the list comprising iron (Fe), cobalt (Co), nickel (Ni), copper (Cu), ruthenium (Ru), rhodium (Rh), palladium (Pd) or Rhodium (Rh), silver (Ag), cerium (Ce), osmium (Os), iridium (Ir), platinum (Pt), gold (Au) or a combination of one or more of these metals.
50. Method according to any one of statements 1 to 49, wherein the catalyst starting material comprises metal nanoparticles comprising or consisting of platinum (Pt) or palladium (Pd) or Rhodium (Rh).
51. Method according to any one of statements 1 to 50, the preferred catalyst starting material is palladium (Pd) or Rhodium (Rh) when the support nanoparticles comprise aluminium oxide (Al₂O₃); or the preferred catalyst starting material is platinum (Pt) when the support nanoparticles comprise cerium oxide, such as CeO₂ or Ce_{0.7}Zr_{0.3}O₂ or Ce_{0.5}Zr_{0.5}O₂.
52. Method according to any one of statements 1 to 51, wherein the method comprises providing a source of UV light, preferably a source of UV light for high vacuum (<10⁻⁴ Pa), preferably oriented towards the catalytic starting material.
53. Method according to any one of statements 1 to 52, wherein the method comprises providing a source of X-rays, preferably a source of soft X-rays for high vacuum (<10⁻⁴ Pa), preferably oriented towards the catalytic starting material.
54. Method according to any one of statements 1 to 53, wherein the method comprises providing a source of an electron beam, preferably oriented towards the catalytic starting material.
55. Method according to any one of statements 1 to 54, wherein the ion beam comprises at least 75% of the selected ions, preferably at least 90% of the selected ions, more preferably at least 95% of the selected ions, still more preferably at least 99% of the selected ions and most preferably consist of only the selected ions.
56. Method according to any one of statements 1 to 55, wherein the step of implanting the catalyst starting material with an ion beam is performed at a pressure of at most 10⁻⁴ Torr, preferably at most 10⁻⁵ Torr, more preferably at most 10⁻⁶ Torr and most preferably at most 10⁻⁷ Torr.
57. Method according to any one of statements 1 to 56, wherein the step of implanting the catalyst starting material with an ion beam is performed at a pressure of at least 3×10⁻⁶ Torr, preferably at least 5×10⁻⁶ Torr more preferably at least 7×10⁻⁶ Torr, even more preferably at least 10×10⁻⁶ Torr and most preferably at least 20×10⁻⁶ Torr.
58. Method according to any one of statements 1 to 57, wherein the step of implanting the catalyst starting material with an ion beam is performed at a pressure of at least 3×10⁻⁶ Torr to at most 10⁻⁴ Torr, preferably at least 5×10⁻⁶ Torr to at most 7×10⁻⁵ Torr, more preferably at least 7×10⁻⁶ Torr to at most 5×10⁻⁵ Torr, even more preferably at least 10×10⁻⁶ Torr to at most 3×10⁻⁵ Torr.
59. Method according to any one of statements 1 to 58, wherein noble gas, such as Ar, Kr or Xe, is injected into the treatment chamber.
60. Method according to any one of statements 1 to 59, wherein the ion beam has an average charge (gₐᵥᵣ) of at least 1.00 to at most 5.00, preferably at least 1.10 to at most 3.00, more preferably at least 1.20 to at most 2.00, even more preferably at least 1.30 to at most 1.75 yet even more preferably at least 1.40 to at most 1.60 and most preferably at least 1.50 to at most 1.55.
61. Method according to any one of statements 1 to 60, wherein the ions in the ion beam have an average energy (Eₐᵥᵣ) of least 10 keV to at most 100 keV, preferably at least 20 keV to at most 90 keV, more preferably at least 30 keV to at most 80 keV, even more preferably at least 40 keV to at most 70 keV and most preferably at least 50 keV to at most 60 keV.
62. Method according to any one of the statements 1 to 61, wherein X follows the following in equations:

(7/Zₐᵥᵣ)×10¹⁸ ions/g<X<(7/Zₐᵥᵣ)×6×10¹⁹ ions/g.
63. Method according to any one of statements 1 to 62, wherein the ratio of the current of the ion beam current to the cross-section area of the ion beam, measured at the point of contact with the catalyst starting material is at least 1.2 μA/mm², preferably at least 2.4 μA/mm², more preferably at least 3.6 μA/mm².
64. Method according to any one of claims 1 to 63, wherein the ratio of the current of the ion beam current to the cross-section area of the ion beam, measured at the point of contact with the catalyst starting material is at most 50 μA/mm², preferably at most 35 μA/mm², more preferably at most 25 μA/mm².
65. Method according to any one of claims 1 to 64, wherein the ion beam dose is comprised between 4.5×10¹⁸ ions/g and 2×10¹⁹ ions/g.
66. Support nanoparticles, catalyst particles, a catalyst surface, a carrier comprising a catalytic surface, a catalyst, or a carrier comprising a catalyst, produced by the method according to any one of statements 1 to 65.
67. Use of the catalyst particles, catalytic surface, or catalyst prepared according to the method according to any one of statements 1 to 65 in NOx, CO, and/or HC (hydrocarbon) emission reduction devices, fuel cells, or catalysts in chemical, in particular petrochemical, reactions.
68. Use of ion implantation in the preparation of catalyst particles, catalytic surfaces or catalysts, preferably by using a method according to any one of statements 1 to 65.
69. Use of a method according to any one of statements 1 to 65 in the preparation of catalyst particles, catalytic surfaces, a catalyst washcoat or catalysts.

The term “average diameter” or Dₐᵥᵣ of a nanoparticle or particle of a metal D_{avr,metal}, support D_{avr,sup}, catalyst D_{avr,cat}, or powder D_{avr,powder} refers to the sum of the diameter of each nanoparticle or particle divided by the total number of nanoparticles or particles. The diameter of a nanoparticle or particle may be determined by TEM or HRTEM analysis. The shape of the nanoparticles or particles may be irregular. For the purpose of the present invention, the diameter of a nanoparticle or particle may be calculated as the diameter of a two-dimensional disk having the same projected area as the nanoparticle or particle in the TEM or HRTEM image. Preferably, to calculate Dₐᵥᵣ, the diameters of at least 20, preferably at least 40 nanoparticles or particles are taken into account.

The analysis of the TEM or HRTEM image may be added by image analysis software ImageJ, developed by the National Institutes of Health, USA to identify the nanoparticles and particles and determine their diameter.

The term “average atomic number” or Zₐᵥᵣ refers to the sum of the atomic number of each ion, divided by the total number of ions.

The invention provides in a method for preparing catalyst particles, comprising the steps of:
a. providing a catalyst starting material;
b. providing an average atomic number Zₐᵥᵣ;
c. selecting an ion beam with a dose X expressed in ions/g, based on the weight of the catalyst starting material wherein X follows the following in equations:

i. (7/Zₐᵥᵣ)×10¹⁸ ions/g<X<(7/Zₐᵥᵣ)×6×10¹⁹ ions/g,
ii. and preferably with an energy of the monocharged ions in the ion beam from at least 10 keV to at most 100 keV; and,
d. implanting the catalyst starting material with an ion beam dose X primarily comprising the selected ions;
   thereby obtaining catalyst particles.

Preferably X follows the following in equation (7/Zₐᵥᵣ)×10¹⁸ ions/g<X<(7/Zₐᵥᵣ)×3×10¹⁹ ions/g:

The ion beam may comprise monocharged ions or a mixture of monocharged and multicharge ions.

The invention provides in a method for preparing a catalyst surface, comprising the steps of:
a. providing a catalyst starting material;
b. providing a metal nanoparticle with an average diameter D_{avr,sup}
c. providing a minimum number of defects N per volume unit of catalyst
d. selecting ions with an average atomic number Zₐᵥᵣ, wherein Zₐᵥᵣ follows the following in equations:

i. INT(0.5×D_{avr,metal}×1/nm)<Zₐᵥᵣ<INT(2.0×D_{avr,metal}×1/nm); and,
e. implanting the catalyst starting material with an ion beam dose primarily comprising the selected ions preferably with an energy of the monocharged ions in the ion beam from at least 10 keV to at most 100 keV;
   thereby obtaining a catalyst surface.

Preferably, the volume of the catalyst or catalyst particles is calculated from the tapped density as determined in ASTM D4164-13(2018).

The invention provides in a method for preparing a catalyst surface, comprising the steps of:
a. providing an ion with an atomic number Z;
b. providing a minimum number of defects N per volume unit of catalyst;
c. selecting a catalyst starting material; and,
d. implanting the catalyst starting material with an ion beam dose primarily comprising the selected ions preferably with an energy of the monocharged ions in the ion beam from at least 10 keV to at most 100 keV;
   thereby obtaining a catalyst surface.

The invention provides in a method for preparing a catalyst surface, comprising the steps of:
a. providing an ion with an atomic number Z;
b. providing a minimum number of defects N per volume unit of catalyst;
c. selecting a catalyst starting material; and,
d. implanting the catalyst starting material with an ion beam dose primarily comprising the selected ions preferably with an energy of the monocharged ions in the ion beam from at least 10 keV to at most 100 keV;
   thereby obtaining a catalyst surface.

Preferably, the number of defects N per volume unit of catalyst or catalyst particle is expressed as amorphous fraction per volume unit of catalyst, wherein the amorphous fraction is determined by X-Ray diffraction and the volume of the catalyst is preferably calculated from the tapped density as determined in ASTM D4164-13(2018).

In some embodiments, the ion beam comprises at least 75% of the selected ions, preferably at least 90% of the selected ions, more preferably at least 95% of the selected ions, still more preferably at least 99% of the selected ions and most preferably consists of only the selected ions.

In some embodiments, Zₐᵥᵣ is at most 20, preferably at most 14, more preferably at most 10, even more preferably at most 7 and most preferably at most 4.

In some embodiments, at least part of the ions, preferably all ions, are derived from atoms with an atomic number Z of at most 18, in particular at most 7, preferably at most 6, more preferably at most 2.

In some embodiments, at least part of the ions, preferably all ions, are derived from helium atoms, argon atoms, oxygen atoms and/or nitrogen atoms.

In some embodiments, at least part of the ions, preferably all ions, are derived from nitrogen atoms.

In some embodiments, at least 50% of the ions, preferably at least 75% of the ions, more preferably at least 90% of the ions, even more preferably at least 95% of the ions and most preferably 100% of the ions are derived from nitrogen atoms.

In some embodiments, at least part of the ions, preferably all ions, are derived from helium atoms, argon atoms.

In some embodiments, at least 50% of the ions, preferably at least 75% of the ions, more preferably at least 90% of the ions, even more preferably at least 95% of the ions and most preferably 100% of the ions are derived from helium atoms, argon atoms.

In some embodiments, the energy E of the ions in the ion beam is at least 10 keV, preferably at least 20 keV, more preferably at least 30 keV, even more preferably at least 40 keV and most preferably at least 50 keV.

In some embodiments, the energy E of the ions in the ion beam is at most 100 keV, preferably at most 90 keV, more preferably at most 80 keV, even more preferably at most 70 keV and most preferably at most 60 keV.

In some embodiments, the energy E of the monocharged ions in the ion beam is at least 10 keV to at most 100 keV, preferably at least 20 keV to at most 90 keV, more preferably at least 30 keV to at most 80 keV, even more preferably at least 40 keV to at most 70 keV and most preferably at least 50 keV to at most 60 keV.

In some embodiments, the ion beam comprises a mixture of differently charged ions, and therefore each differently charged ion may have a different energy. This is the result that the energy of the ions in the ion beam is the results of being accelerated by a voltage, preferably the extraction voltage. For example a nitrogen ion beam may comprise 58% N⁺; 32% N⁺, 9% N³⁺ and 1% N⁺⁴. When these ions are accelerated by a extraction voltage of 40 kV, the ion beam is made up of 58% of nitrogen ions with an energy of 40 keV, 32% of nitrogen ions with an energy of 80 keV, 9% of nitrogen ions with an energy of 120 keV and 1% of nitrogen ions with an energy of 160 keV.

In some embodiments, the ion beam has an average charge (gₐᵥᵣ) of at least 1.00 to at most 5.00, preferably at least 1.10 to at most 3.00, more preferably at least 1.20 to at most 2.00, even more preferably at least 1.30 to at most 1.75 yet even more preferably at least 1.40 to at most 1.60 and most preferably at least 1.50 to at most 1.55. Herein, gₐᵥᵣ is the sum of all the charges in the ion beam divided by the number of ions the ion beam.

In some embodiments, the ions in the ion beam have an average energy (Eₐᵥᵣ) of least 10 keV to at most 100 keV, preferably at least 20 keV to at most 90 keV, more preferably at least 30 keV to at most 80 keV, even more preferably at least 40 keV to at most 70 keV and most preferably at least 50 keV to at most 60 keV. Herein Eₐᵥᵣ is the sum of all the energy values in the ion beam divided by the number of ions in the ion beam. Therefore, an ion beam with an gₐᵥᵣ 1.53 which is extracted by an extraction voltage of 40 kV has an Eₐᵥᵣ of 61.2 keV.

In some embodiments, the ions with the highest energy in the ion beam have an energy of at most 200 keV. In some embodiments, the ions with the lowest energy in the ion beam have an energy of at least 10 keV.

In some embodiments, the ion beam is generated by an ECR plasma confined with permanent magnets. Preferably the ion beam source comprises a mono- and multicharged ions plasma confined with permanent magnets which is generated by electron cyclotron resonance (ECR) using a high frequency, such as 2.45; 7.50 or 10.00 GHz. A monocharged ion is an ion bearing a single positive charge, a multicharged ion is an ion bearing more than one positive charge. The ion beam is then extracted to generate mono-multi-energies ions beam penetrating more deeply in the catalytic starting material. This kind of ion beam is more efficient to treat nanoparticles or catalytic material inside other material, such as support, or other catalytic material. Plasma filament ion beam sources and ECR Plasma Immersion ion implantation (PIII) sources generate molecular ions with lower charges states which have the drawbacks to be heavier with less energy, in others words to have reduced depth ranges to treat nanoparticles or catalyst.

In some embodiments, the ion beam dose is at least 10¹³ ions/cm², preferably at least 10¹⁴ ions/cm², even more preferably at least 10¹⁵ ions/cm² at the point of contact with the catalyst starting material, where the catalyst starting material is considered to be forming an essentially flat surface

In some embodiments, the ion beam dose is at most 10¹⁸ ions/cm², preferably at most 10¹⁷ ions/cm², even more preferably at most 10¹⁶ ions/cm² at the point of contact with the catalyst starting material, where the catalyst starting material is considered to be forming an essentially flat surface.

In some embodiments, the ion beam dose is at least 10¹³ ions/cm² to at most 10¹⁸ ions/cm², preferably at least 10¹⁴ ions/cm² to at most 10¹⁷ ions/cm², even more preferably at least 10¹⁵ ions/cm² to at most 10¹⁶ ions/cm² at the point of contact with the catalyst starting material, where the catalyst starting material is considered to be forming an essentially flat surface.

In some embodiments, the total ion beam dose is split into m separate doses, and wherein the catalytic starting material is mixed or stirred each time between the m different ion implantation treatments, preferably m is at least 4 to at most 64, more preferably at least 8 to at most 32, even more preferably at least 12 to at most 24 and most preferably at least 16 to at most 18. An amount of powder may be spread over a given area or surface and exposed to the ion beam m times to obtain a total ion dose. Each time, between the different doses, the powder may be mixed and may be spread again over the original area to allows to obtain a homogeneous treatment for the powder starting material. In some embodiments, m is at least equal to the ratio of the mean thickness of the powder spread over a given area and the mean free path of the ions inside the powder. The free path being the path ions travel inside the powder before they are stopped by the powder.

In some embodiments, the advancement step of the ion beam is at least 1% to at most 50%, preferably at least 2% to at most 40%, more preferably at least 5% to at most 30%, even more preferably at least 7% to at most 20% and most preferably at least 10% to at most 15%. The ion beam may move in a series of round trips separated by a distance corresponding to a fraction of the ion beam diameter called advancement step. A step of 10% for a beam with a diameter of 22.5 mm, means that for each round trip a shift of 2.25 mm is performed. The advancement step may result in a high surface homogeneity of the treatment, preferably regardless the intensity distribution of the ion beam, which may be for instance be a Gaussian shape with more intensity at the centre and less intensity at the periphery.

In some embodiments, the method comprises n different implanting steps with n multiple doses Xᵢ, preferably wherein each dose Xᵢ is X/n, X being the total ion beam dose, i.e. the sum of the n doses Xᵢ. In some embodiments, the different implanting steps differ by at least one implantation parameter, e.g. different ions may be used in different steps. Preferably n is at most 3, more preferably n is at most 2, and most preferably n is 1.

In some embodiments, the method comprises implanting the catalyst starting material with an ion beam that is performed at a pressure of at most 10⁻⁴ Torr, preferably at most 10⁻⁵ Torr, more preferably at most 10⁻⁶ Torr and most preferably at most 10⁻⁷ Torr.

In some embodiments, noble gas, such as Ar, Kr or Xe, is injected into the treatment chamber, preferably in lower vacuum levels, such as lower than 10⁻⁴ Torr, preferably lower than 10⁻⁵ Torr, more preferably lower than 10⁻⁶ Torr and most preferably lower than 10⁻⁷ Torr. These noble gasses at least partially suppress the static electricity induced by the ion implantation of the catalytic material.

In some embodiments, the pressure in the treatment chamber is at least 3.10⁻⁶ Torr, preferably at least 5.10⁻⁶ Torr more preferably at least 7.10⁻⁶ Torr, even more preferably at least 10.10⁻⁶ Torr and most preferably at least 20.10⁻⁶ Torr. These vacuum levels help to at least partially neutralize electrostatic barrier induced by the implanted ions.

In some embodiments, the metal nanoparticles comprise or consist of a transition metal, preferably a noble metal. In some embodiments, the metal nanoparticles comprise or consist of a rare earth metal.

In some embodiments, the metal nanoparticles comprise or consist of material is selected from the list iron (Fe), cobalt (Co), nickel (Ni), copper (Cu), ruthenium (Ru), rhodium (Rh), palladium (Pd) or Rhodium (Rh), silver (Ag), cerium (Ce), osmium (Os), iridium (Ir), platinum (Pt), gold (Au) or a combination of one or more of these metals.

In some embodiments, the preferred metal nanoparticle material is selected from platinum (Pt) or rhodium (Rh) when the support is cerium oxide, such as CeO₂ or Ce_{0.7}Zr_{0.3}O₂ or Ce_{0.5}Zr_{0.5}O₂.

In some embodiments, the preferred catalyst starting material is palladium (Pd) or Rhodium (Rh) when the support is aluminium oxide (Al₂O₃).

In some embodiments, the catalyst starting material comprises catalyst particles and support nanoparticles. Preferably doe these catalyst particles and support nanoparticles aggregates, preferably are these aggregates tightly bound together. These aggregates may form an agglomerate particles, which is often referred to as a catalytic powder.

In some embodiments, the catalyst starting material is a catalytic powder.

In some embodiments, the oxidation state of the catalyst starting material and/or the support is changed by the inventive method.

In some embodiments, defects are created in the catalyst material and in the support.

In some embodiments, the inventive method increases the amorphous fraction of the catalyst, catalyst surface or catalytic nanoparticles by at least 1%, preferably at least 2%, more preferably at least 5%, even more preferably at least 7%, yet more preferably at least 10%, still yet preferably at least 15% and most preferably at least 20%, compared to the starting material, preferably the amorphous fraction being determined by X-ray diffraction.

The invention further provides catalytic nanoparticles or a support comprising catalytic nanoparticles produced by a method according to the invention. In some embodiments, the catalyst starting material is provided on a support. In some embodiments, the method is for preparing catalyst particles on a support, preferably physically or chemically attached to a support.

The term “support” refers to a material that holds the catalytic material in place. The support may be inactive or may show a catalytic activity itself. The support may be macroscopic and allows to fixate the catalytic material in a catalytic converter.

In some embodiments, the support is an aluminium oxide preferably Al₂O₃, or a cerium oxide, preferably CeO₂ or Ce_{0.7}Zr_{0.3}O₂ or Ce_{0.5}Zr_{0.5}O₂.

In some embodiments, the ratio of the weight of the catalytic starting material over the weight of the support is at least 0.1 wt % to at most 5.0 wt %, preferably 0.3 wt % to at most 3.0 wt %, more preferably at least 0.5 wt % to at most 2.0 wt %, and most preferably at least 0.7 wt % to at most 1.5 wt %.

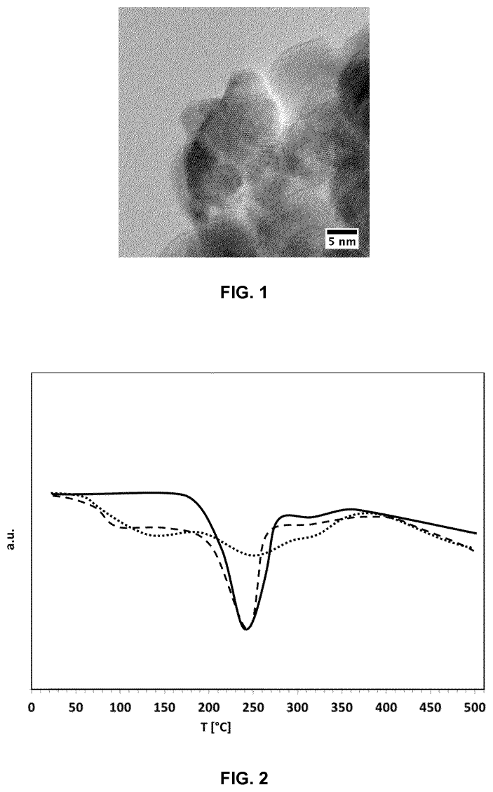

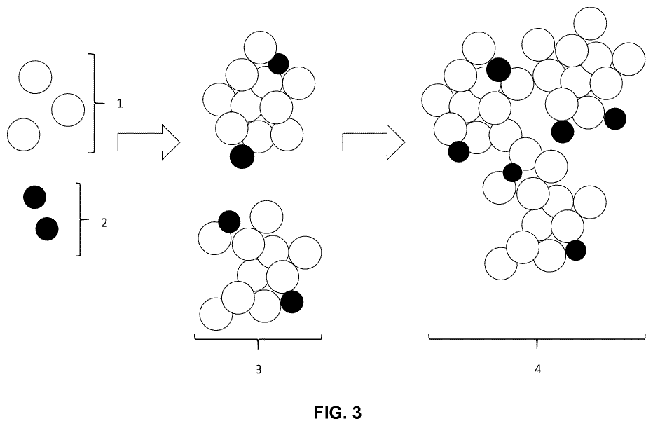

These catalytic nanoparticles may comprise defects, such as surface defects like terraces, surface steps, kinks and vacancies, as can be seen in FIG. 1. Due to the defects the activity of the catalyst may be increased These induces surface imperfections can be seen by high-resolution transmission electron microscopy (HRTEM) analysis. These defects contribute to the amorphisation of the catalyst material and/or the support. X-ray diffraction may be a method to quantify the amorphous fraction. It has been observed that a larger number of defects or a larger amorphous fraction created by the inventive method, provides an increase in catalytic activity, compared to the untreated catalyst starting material.

In some embodiments, a typical pattern of defects has been observed after a method according to an embodiment of the invention has been carried out on a catalytic starting material.

In some embodiments, the catalyst starting material is provided on a support and is mixed intermittently or continuously, so as to uniformly distribute the implanted ions in the catalyst starting material. Advantageously a carrier or support is used that provides continuous mixed during implantation for example a vibrating plate or bowl, a rotary bowl or a rotary drum. Preferably the carrier combines rotating and vibrating movements. It has been observed that the resulting implanted catalyst material is more homogeneously implanted when continuous mixing is provided, such as for example in a rotary bowl or drum. The catalyst starting material on the support shall advantageously form a layer of catalyst starting material having a thickness that is larger than the implantation depth of the ions in the catalyst starting material to avoid implanting ions in the support.

In some embodiments, the catalyst starting material is provided on a carrier or support comprising means for dissipating an static charges. For examples the support may comprise or consist of an electrically conducting material, such as a metal, and be electrically grounded.

In ion implantation on solid substrates, the ion implantation dose is usually expressed using the unit ions/cm². This dosage may be calculated using the following formula (units omitted):

$$D = \frac{I \times T}{S \times q}$$

wherein D is the dosage [ions/cm²], / is the ion beam current [A], tis the implantation time [s], S is the surface area [cm²], q is the elementary charge 1.6×10⁻¹⁹ [Coulomb]. This formula is easily adapted for mixtures of single charge and multicharge ions.

In some embodiments the ion dose is conveniently expressed using the unit ions/g. This dosage may be calculated using the following formula (units omitted):

$$D = \frac{I \times T}{Q \times q}$$

wherein, with the units in square brackets, D is the dosage [ions/cm²], / is the ion beam current [A], t is the implantation time [s], Q is the quantity of implanted catalyst starting material [g], q is the elementary charge 1.6×10⁻¹⁹ [Coulomb]. This formula is easily adapted for mixtures of single charge and multicharge ions.

When the catalyst starting material is evenly spread on a flat substrate, this dosage can be derived from the dosage expressed in ions/cm² and the surface density σ, in g/cm², of the evenly distributed catalyst starting material as follows:

$$dosage [ \frac{ions}{g} ] = \frac{dosage [ \frac{ions}{{cm}^{2}} ]}{σ [ \frac{g}{{cm}^{2}} ]}$$

It has been found that the inventive method may create strong modification of physical and textural properties of the catalyst material.

The inventors have noticed that ion implantation can create Frenkel pairs. When an the energy of an ion is higher than a certain energy threshold, atoms on the surface of the catalytic starting material can be expulsed from its site by the incident ion, generating in one side an interstitial atom inserted inside close lattices with a high energy storage and in the other side a vacancy at its original site. Crystal deformation may be detected by X ray crystallography.

These kinds of modifications can be described as a strong amorphisation of the product, corresponding to a very important increase of defective units on all the surface of the powder.

Increase of vacancies and creation of “terraces” can participated to described this physical modification of the product.

Therefore, the inventive method may result in an increased amorphisation, increased number of defects such as vacancy, a higher oxygen mobility, which may be translated in a high reducibility.

The invention may further comprise means to reduce electrostatic charging of the catalyst starting material during ion implantation. According to an embodiment of the invention, the ECR ion source is associated with an electron beam or electron gun. An electron beam which is a well-known device for producing a beam of electrons by extracting in a vacuum electrons from a conductive material accelerating the electrons with an electric field. In an embodiment of the present invention a cold field emission electron gun is preferably used. For this purpose, the electron gun comprises an anode, for example of graphite, in which is provided an orifice, and a metal cathode in the form of a very fine point. A high electrical voltage is applied by means of an electric generator between the anode 18 and the metal cathode. The high voltage produces a very strong electric field at the tip of the metal cathode which makes it possible to extract electrons from the tip of the metal cathode and to accelerate them so as to create an electron beam which propagates through the anode's orifice. In alternate embodiment the extraction of electrons from the tip of the metal cathode may be thermally assisted. The electron beam may be oriented towards the catalyst starting material being implanted and neutralize the charges as they build up during ion implantation. The electron beam produced by the electron gun may also be oriented so as to pass through the ion beam. The electron beam's electrons recombine with ions, which causes a reduction or even a cancellation of the electric charge of these ions, so that, very often, they are neutral atoms (or at least with a lower electrostatic charge) which, carried away by their kinetic energy, will come to strike the surface of catalyst starting material.

In certain embodiments of the present invention the means to reduce electrostatic charging of the catalyst starting material during ion implantation are based on photoionization. Photoionization utilizes light to generate ions that neutralize electrostatic charges. When soft X-rays or vacuum ultraviolet (VUV) light hits a stable atom or molecule, normally residual atoms or molecules in a vacuum, an electron is ejected out of the atom or molecule leaving behind a positive ion (positive polarity atom or molecule) The ejected electron then combines with another stable atom or molecule to form a negative ion (atom or molecule of negative polarity). The ions generated near a charged object, for example catalyst starting material being ion implanted, are then attracted to the charged object to neutralize the electrostatic charges. All other generated ions return to the atoms or molecules from which they were ejected.

The invention further also provides in a use of the catalyst particles prepared according to the method according to the invention in NOx, CO, and/or HC emission reduction devices, fuel cells, or catalyst in chemical, in particular petrochemical, reactions.

It is to be understood that although preferred embodiments and/or materials have been discussed for providing embodiments according to the present invention, various modifications or changes may be made without departing from the scope and spirit of this invention.

The invention will be more readily understood by reference to the following examples, which are included merely for purpose of illustration of certain aspects and embodiments of the present invention and are not intended to limit the invention.

### EXAMPLES

Catalytic activity test 1—Temperature programmed oxidation (TPO) test
a. 20 mg catalytic test material is placed on a disk with a diameter of 16 mm and an atmosphere is placed over the test material at a gas hourly space velocity (GHSV) of 70 m³ kg⁻¹ h⁻¹. The atmosphere during the oxidation test consists of 10 vol % O₂, 2000 ppm CO, 2000 ppm CH₄, 2000 ppm C₃H₆, 2000 ppm C₆H₁₄, with the remainder being Argon, wherein the ppm is based on volume parts.
b. The catalytic test material is subjected to 3 cycles in said atmosphere, each cycle existing out of:
   i. equilibrating for 90 minutes at 20° C.;
   ii. heating up at a rate of 2° C. min⁻¹ until a temperature of 550° C. is reached;
   iii. equilibrating at 550° C. for 2 hours; and,
   iv. cooling at 4° C. min⁻¹ to 20° C.
c. When a pre-treatment is carried out, prior to the 3 cycles, the catalytic test material is first subjected to a pre-treatment in an atmosphere consisting of 10 vol % O₂ and 90 vol % Argon, wherein the catalytic test material is heated from 20° C. to 550° C. at a rate of 2° C. min⁻¹, equilibrated at 550° C. for 1 hours, and cooled to 20° C. at a rate of 4° C. min⁻¹.

Catalytic activity test 2—Temperature programmed reduction (TPR)
a. 20 mg catalytic test material is placed on a disk with a diameter of 16 mm. Optionally, the test material is submitted to a heating step in an Argon atmosphere wherein the test material is heated starting from room temperature to a temperature of 550° C. at a heating rate of 5° C. min⁻¹, at 550° C. the testing material is equilibrated for 1 hour before it is cooled down to 20° C. at a rate of 5° C. min⁻¹.
b. After this optional initial heating step, the test material on the disk is placed in an atmosphere consisting of 4000 ppm H₂, the rest being Argon being paced over the test material at a flow rate of 20 cm³ min⁻¹. The test material is equilibrated for 40 min at 20° C. before it is heated to 550° C. at a rate of 5° C. min⁻¹. At 550° C. the test material is equilibrated for 1.5 hour, before it is cooled down at 5° C./min to a temperature of 20° C. The H₂ concentration in the measurement cell is monitored to evaluate the test material's efficiency.

Catalytic activity test 3—CO conversion.
a. 20 mg catalytic test material is placed in a quartz tubular reactor surrounded by a K-type thermocouple equipped furnace. The catalyst was placed in the middle of the reactor.
b. An atmosphere consisting of 1% CO+205% O₂, the rest being Argon being paced through the inlet of the quartz tube, over the test material at a flow rate of 20 cm³ min⁻¹. The test material is equilibrated for 40 min at 20° C. before it is heated to 550° C. at a rate of 5° C. min⁻¹. At 550° C. the test material is equilibrated for 1.5 hour, before it is cooled down at 5° C./min to a temperature of 20° C. The CO concentration at the outlet of the quartz tube is measured using mass spectroscopy, gas chromatography or Fourier-transform infrared (FTIR) spectroscopy, depending of the precision required and the concentration of CO.

In examples 1 to 6 below, the starting materials was poorly distributed, covering only 30% to 50% of the surface undergoing ion implantation over which the starting material is spread. This means that 30-50% of the ions arriving at the surface are implanted into the starting material, and 50 to 70% of the ions arriving at the surface are not implanted in the starting material.

In the examples below the metal nanoparticles have an average diameter comprised between 0.1 and 1 nm, the support nanoparticles have an average diameter comprised between 5 and 10 nm. The catalytic particles formed by aggregates of metal nanoparticles and support nanoparticles have an average diameter comprised between 90 and 100 nm.

### Example 1

Starting material 1, 600 mg Pt/Ce_{0.68}Zr_{0.32}O₂, was placed in a microimplantor designed by the company Quertech, now Ionics, including an ECR (Electron Cyclotron Resonance) ion source powered by a 10 GHz and 50 W HF amplifier, and an ion extraction system of 10 kV (kiloVolt). The plasma of the ion source was confined by permanent magnets allowing the production of monocharged and multicharged ions).

600 mg of Pt/Ce_{0.68}Zr_{0.32}O₂ catalyst particles agglomerated in powder form was spread over a surface of 400 cm² and submitted to 16 treatments with a partial dose of ions of 5×10 ¹⁵ ions/cm², between each treatment the powder was mixed and then spread again on the same surface of 400 cm². Due to the poor distribution mentioned above only about 120 to 200 cm² are effectively covered by the starting material. The surface density of the catalyst particles is thus 0.003 to 0.005 g/cm² and the resulting dosage is between 1.60×10 ¹⁹ to 2.67×10 ¹⁹ ions/g. The dosage is the same for examples 2, 3, 5, 6, and 6′. The treatment was performed with mono and multicharged nitrogen ions (58% N⁺, 32% N²⁺, 9% N³⁺, 1% N⁴⁺), extracted by an extraction voltage of 35 kV, i.e. with a mean charge (gₐᵣᵥ) state of 1.53 and mean energy Eₐᵥᵣ equal to 53 keV. The moving of the ion beam consisted in a succession of round-trips covering a total area of 68×28 cm² with a speed of 80 mm/s, each round trip was performed with an advancement step corresponding to a fraction of the ion beam diameter of 30%, in other words corresponding to an absolute shift of 6.75 mm (30% of 22.5 mm). The ion beam current to ion beam cross-section area ratio was 2.52 μA/mm². The pressure in the treatment chamber was 10⁻⁵ mbar. By covering a total area that is much larger than the area surface where the catalyst is spread, constant speed over the catalyst is ensured and the turn-around can be performed away from the catalyst.

### Example 2

Starting material 2, 600 mg of Pt/γ-Al₂O₃ catalyst particles agglomerated in powder form, was spread over a surface of 400 cm² and submitted to 16 treatments with a partial dose of ions of 5×10 ¹⁵ ions/cm², between each treatment the powder was mixed and then spread again on the same area of 400 cm². The treatment was performed with mono and multicharged nitrogen ions (58% N⁺, 32% N²⁺, 9% N³⁺, 1% N⁴⁺) extracted by an extraction voltage of 35 kV, i.e. with a mean charge state of 1.53 and mean energy Eₐᵥᵣ equal to 53 keV. The moving of the ion beam consisted in a succession of round-trips on a surface treatment of 68×28 cm² with a speed of 80 mm/s, each round trip was performed with an advancement step corresponding to a fraction of the ion beam diameter of 30%, in other words corresponding to an absolute shift of 6.75 mm (30% of 22.5 mm). The ion beam current to ion beam cross-section area ratio was 2.52 μA/mm². The pressure in the treatment chamber was 10⁻⁵ mbar.

### Example 3

Starting material 3, 600 mg of Ce_{0.68}Zr_{0.32}O₂ support nanoparticles in agglomerated powder from, was spread over an area of 400 cm² and submitted to 16 treatments with a partial dose of ions of 5×10 ¹⁵ ions/cm², between each treatment the powder was mixed and then spread again on the same area of 400 cm². The treatment was performed with mono and multicharged nitrogen ions (58% N⁺, 32% N²⁺, 9% N³⁺, 1% N⁴⁺) extracted by an extraction voltage of 35 kV, i.e. with a mean charge state of 1.53 and mean energy Eₐᵥᵣ equal to 53 keV. The moving of the ion beam consisted in a succession of round-trips covering a total area of 68×28 cm² with a speed of 80 mm/s, each round trip was performed with an advancement step corresponding to a fraction of the ion beam diameter of 30%, in other words corresponding to an absolute shift of 6.75 mm (30% of 22.5 mm). The ion beam current to ion beam cross-section area ratio was 2.52 μA/mm². The pressure in the treatment chamber was 10⁻⁵ mbar.

### Example 4

Starting material 4, catalytic particles of 1% Pt/Al₂O₃ Gamma, were treated by nitrogen ion implantation to obtain Example 4.

The treatment consisted in spreading 150 mg of starting material 4 in powder form (1% Pt/Al₂O₃ Gamma) over a surface of 10 cm² and treating it according to 2 treatments each one performed with a partial ion dose of 4×10¹⁷ ions/cm². Due to the poor distribution mentioned above only about 3 to 5cm² are effectively covered by the starting material. Between each treatment the powder was mixed and then spread again on the same area of 10 cm². The surface density of the catalyst particles is thus 0.03 to 0.05g/cm² and the resulting dosage is 1.60×10¹⁹ to 2.67×10¹⁹ ions/g. The treatment was performed with mono and multicharged nitrogen ions (58% N⁺, 32% N²⁺, 9% N³⁺, 1% N⁴⁺) extracted by an extraction voltage of 35 kV, i.e. with a mean charge state of 1.53 and a mean energy Eₐᵥᵣ equal to 53 keV. The ion beam had an intensity of 1 mA, a diameter of 22.5 mm and swept a total area of 15×15 cm². The moving of the ion beam consisted in a succession of round-trips with a speed of 80 mm/s, each round trip was performed with a step corresponding to a fraction of the ion beam diameter of 30%, in other words corresponding to an absolute shift of 6.75 mm (30% of 22.5 mm). The ion beam current to ion beam cross-section area ratio was 2.52 μA/mm². The pressure in the treatment chamber was 10⁻⁵ mbar.

Both starting material and Example 4, were subjected to 3 TPO cycles as described herein and were aged in 10% H₂O/N₂ stream at 600° C. during 5 h, GHSV=20 m³ kg⁻¹ h⁻¹. the Platinum (Pt) dispersion (%) was measured before TPO, after 3 TPO cycles and after aging. The Platinum dispersion is determined by reducing the catalyst powder in a H₂/Argon atmosphere at 100 Torr, comprising 10-20% H₂ at a temperature of 200° C. for 30 minutes, then the catalyst powder is exposed to CO and the CO adsorption is observed. The dispersion (%) is the ratio of the amount of adsorbed CO to the amount of platinum. The results are shown in Table 1.

TABLE 1
effect of aging

| | Pt dispersion | Pt dispersion After | Pt dispersion After |
|---|---|---|---|
| | Before TPO | 3 TPO cycles | ageing |
| before ion | 38 (±2) % | 10% | 15% |
| implantation | | | |
| Example 4 | 35% | 11% | 26% |

### Example 5

In this case a resistance to hydrothermal aging is measured at 750° C. A better metal dispersion of the catalyst is observed after treatment: the Pt dispersion is 27% for the treated powder instead of 17% for the reference powder. The aging process was performed in 10% H₂O/N₂ at 750° C. during 5 h, GHSV=20 m³ kg⁻¹ h⁻¹.

The treatment of example 5 consisted in spreading 600 mg 1% Pt/Al₂O₃ Gamma on a surface of 400 cm² and treating it according to 16 treatments each one performed with an ion dose of 5×10¹⁵ ions/cm². Between each treatment the powder was mixed and spread again on the same area of 400 cm². The treatment was performed with mono and multicharged nitrogen ions (58% N⁺, 32% N²⁺, 9% N³⁺, 1% N⁴⁺) extracted from the ion source with an extraction voltage of 35 kV, in other words with a mean charge state of 1.53 and a mean energy Eₐᵥᵣ equal to 53 keV. The ion beam with a diameter of 22.5 mm swept a total area of 68×28 cm². The moving of the ion beam consisted in a succession of round-trips with a speed of 80 mm/s, each round trip was performed with a step corresponding to fraction of the ion beam diameter of 30%, equivalent to an absolute shift of 6.75 mm (30% of 22.5 mm). The ion beam current to ion beam cross-section area ratio was 2.52 μA/mm². The pressure in the treatment chamber was 10⁻⁵ mbar.

TABLE 2
effect of aging

| | Pt dispersion | Pt dispersion after |
|---|---|---|
| | Before aging | aging at 750° C. |
| 1% Pt/Al₂O₃ Gamma before | 48 (±2) % | 16 (±2) % |
| ion implantation | | |
| 1% Pt/Al₂O₃ Gamma of | 34% | 27% |
| example 5 | | |

### Examples 6 and 6′

FIG. 2 shows that results for the first cycle TPR, wherein H₂ consumption (shown in arbitrary units) is measured for untreated 1% Pt/Ce_{0.7}Zr_{0.3}O₂ or Ce_{0.5}Zr_{0.5}O₂ powder (solid line) and for ion implanted powder according to example 6 (dashed line) and for ion implanted powder according to example 6′ (dotted line).

For example 6 the ion implantation conditions consisted in spreading about 600 mg of 1% Pt/Ce_{0.7}Zr_{0.3}O₂ powder over an area of 400 cm² and treating it according to 16 treatments each one performed with a partial ion dose of 5×10¹⁵ ions/cm². Between each treatment the powder was mixed and spread again on the same area of 400 cm². The treatment was done with mono and multicharged nitrogen ions (58% N⁺ 32% N²⁺, 9% N³⁺, 1% N⁴⁺) extracted by an extraction voltage of 35 kV, i.e. with a mean charge state of 1.53 and mean energy Eₐᵥᵣ equal to 53 keV. The ion beam with a diameter of 22.5 mm swept a total area of 68×28 cm². The moving of the ion beam consisted in a succession of round-trips with a speed of 80 mm/s, each round trip was performed with a step corresponding to a fraction of the ion beam diameter of 30%, in other words corresponding to an absolute shift of 6.75 mm (30% of 22.5 mm). The ion beam current to ion beam diameter ratio was 2.52 μA/mm². The pressure in the treatment chamber was 10⁻⁵ mbar.

For example 6′ the same ion implantation treatment as for example 6 was executed twice. The resulting dosage is between 3.20×10 ¹⁹ and 5.34×10¹⁹ ions/g

As can be seen in FIG. 2, the temperature where the peak catalytic activity occurs shifted from above 240° C. for the untreated particles to between 130° C. and 150° C. for example 6′, even to between 90° C. and 100° C. for example 6.

In examples 7, 7′ and 7″, 600 mg of 1% Pt/Ce_{0.7}Zr_{0.3}O₂ was provided in a vibrating bowl centered below the ion beam. The diameter of the powder at its surface was slightly larger than the diameter of the diameter of the ion beam. The treatment was done with mono and multicharged nitrogen ions (58% N⁺ 32% N²⁺, 9% N³⁺, 1% N⁴⁺) extracted by an extraction voltage of 35 kV, i.e. with a mean charge state of 1.53 and mean energy Eₐᵣᵥ equal to 53 keV. The total dose could be implanted without interruption while the bowl was kept vibrating.

Example 7, 7′ and 7″ were tested in the same manner as Examples 6 and 6′. Table 3 shows the corresponding dosages and temperatures of peak catalytic activity.

TABLE 3
Dosages and temperatures of peak catalytic activity

| | Dosage | Temperature of peak |
|---|---|---|
| Example | [ions/g] | catalytic activity |
| 7 | 4.5 × 10¹⁸ | 70° C. to 160° C. |
| 7′ | 8 × 10¹⁸ | 140° C. to 150° C. |
| 7″ | 2.3 × 10¹⁹ | 90° C. to 110° C. |

Experiments using a vibrating rotary bowl, equipped with vanes to improve mixing showed similar results as in Examples 7, 7′ and 7″. Vibrating rotary bowls however could be used with larger quantities of catalyst starting material, up to 20 g batches could thus be treated. At lower doses such as in Example 7 reliable implantation is difficult as can be seen from the wide range of resulting catalytic activity peak temperature. Higher doses such as in Example 7″ are preferred as they lead to less variation in the resulting catalytic activity.

Means to reduce build-up of static electricity have been tested. A Vacuum ultraviolet (VUV) Ionizer was found to reduce the amount of material lost due to build-up of electrostatic charges. Also an electrically grounded receptacle for the catalyst starting material reduced the amount of material lost due to static build-up at least 50%. Preferably the catalyst starting material comprises metal nanoparticles to further reduce electrostatic charging and related losses of material during implantation.

When a catalyst starting material comprising nanoparticles from a platinum group metal, such as for example platinum or rhodium, and further comprising support nanoparticles comprising cerium and zirconium oxide, were implanted with ions of nitrogen, oxygen or helium, preferably of nitrogen, with an ion beam dose comprised between 4.5×10¹⁸ ions/g and 2×10¹⁹ ions/g, it was surprisingly found that not only the temperature of peak catalytic activity decreased, but also the CO conversion efficiency improved, with a temperature of 50% conversion of CO being lowered from about 150° C. to about 120° C. in the case of a 0.5% Rh/Ce_{0.7}Zr_{0.2}O₂ catalyst.

1. Method A method for preparing catalyst particles, comprising:
providing a catalyst starting material;
providing an average atomic number Zavr;
providing an ion beam having an ion beam current and
selecting an ion beam dose X expressed in ions/g, based on a weight of the catalyst starting material, wherein X follows the following equation:
(7/Zavr)×10¹⁸ ions/g<X<(7/Zavr)×6×10¹⁹ ions/g; and,
implanting the catalyst starting material with an ion beam dose X primarily comprising the selected ions, wherein a ratio of a current of the ion beam current to a cross-section area of the ion beam, measured at a point of contact with the catalyst starting material is at least 1.2 μA/mm², thereby obtaining a catalyst.

2. The method according to claim 1, wherein the ion beam is generated by a plasma filament ion beam source or an electron cyclotron resonance (ECR) plasma source.

3. The method according to claim 1, wherein the catalyst starting material comprises catalyst particles made of aggregates of support nanoparticles with surface attached metal nanoparticles.

4. The method according to claim 3, wherein the support comprises an aluminium oxide, a cerium oxide, a zirconium oxide, a titanium oxide or a zeolite or a mixture of any two or more of these materials.

5. The method according to claim 3, wherein a ratio of a weight of the metal nanoparticles over a weight of the support nanoparticles is at least 0.1 wt % to at most 5.0 wt.

6. The method according to claim 1, wherein at least part of the ions are derived from atoms with an atomic number Z of at most 18.

7. The method according to claim 1, wherein at least part of the ions are derived from helium atoms, argon atoms, oxygen atoms and/or nitrogen atoms.

8. The method according to claim 1, wherein Zavr is at most 20.

9. The method according to claim 1, wherein a metal nanoparticle size Davr is at least 0.5 nm to at most 10 nm.

10. The method according to claim 1, wherein an incident angle between the ion beam and a surface normal is 0° to at most 45°.

11. The method according to claim 1, wherein the catalyst starting material comprises metal nanoparticles comprising a transition metal.

12. The method according to claim 1, wherein the catalyst starting material comprises metal nanoparticles comprising platinum (Pt) or palladium (Pd) or Rhodium (Rh).

13. The method according to claim 1, wherein the ratio of the current of the ion beam current to the cross-section area of the ion beam, measured at the point of contact with the catalyst starting material is at least 2.4 μA/mm².

14. The method according to claim 1, wherein the ratio of the current of the ion beam current to the cross-section area of the ion beam, measured at the point of contact with the catalyst starting material is at most 50 μA/mm², preferably at most 35 μA/mm², more preferably at most 25 μA/mm².

15. A catalytic powder comprising catalyst particles produced by a method according to claim 1.

16. A catalyst washcoat comprising particles produced by a method according to claim 1.

17. (canceled)

18. The method according to claim 1, wherein an energy of the monocharged ions in the ion beam is from at least 10 keV to at most 100 keV.

19. The method according to claim 3, wherein a weight of the support nanoparticles is at least 0.3 wt % to at most 3.0 wt %.

20. The method according to claim 1, wherein all of the ions are derived from atoms with an atomic number Z of at most 7.

21. The method according to claim 1, wherein Zavr is at most 14.
